(19) United States
(12) Patent Application Publication
(10) Pub. No.: US 2017/0243999 A1
(43) Pub. Date: Aug. 24, 2017

(54) SOLAR CELL

(71) Applicant: Electronics and Telecommunications Research Institute, Daejeon (KR)

(72) Inventors: Jae-hyung WI, Daejeon (KR); Yong-Duck CHUNG, Daejeon (KR); Woo Jung LEE, Seoul (KR); Daehyung CHO, Daejeon (KR); Won Seok HAN, Daejeon (KR)

(73) Assignee: Electronics and Telecommunications Research Institute, Daejeon (KR)

(21) Appl. No.: 15/434,718

(22) Filed: Feb. 16, 2017

(30) Foreign Application Priority Data
Feb. 24, 2016 (KR) 10-2016-0021640

(51) Int. Cl. H01L 31/0725; H01L 31/0224; H01L 31/18; H01L 31/0749

(52) U.S. Cl. CPC H01L 31/0725; H01L 31/0749; H01L 31/022425; H01L 31/18

(57) ABSTRACT

A solar cell according to embodiments of the inventive concept includes a back electrode on a substrate, a first light absorbing layer including gallium (Ga) and indium (In) on the back electrode, a first buffer layer on the first light absorbing layer, a first window layer on the first buffer layer, a second light absorbing layer including

Ga on the first window layer, a second buffer layer on the second light absorbing layer, and a second window layer on the second buffer layer, wherein a composition ratio of (Ga)/(Ga+In) of the first light absorbing layer is lower than that of the second light absorbing layer.

### CROSS-REFERENCE TO RELATED APPLICATIONS

This U.S. non-provisional patent application claims priority under 35 U.S.C. §119 of Korean Patent Application No. 10-2016-0021640, filed on Feb. 24, 2016, the entire contents of which are hereby incorporated by reference.

### BACKGROUND OF THE INVENTION

The present disclosure herein relates to solar cells, and more particularly, to tandem-type solar cells.

A solar cell is a semiconductor device which directly converts solar light into electricity. Solar cell techniques aim at developing a large-area, low-cost, and high-efficiency solar cell.

A light absorbing layer of a thin-film solar cell converts light energy into electrical energy by absorbing solar light to form electron-hole pairs. With respect to the thin-film solar cell, its energy payback time is shorter than that of a silicon solar cell, and an ultra-thin thin-film solar cell and a large-area thin-film solar cell may be fabricated. Thus, it is expected for the thin-film solar cell that innovative manufacturing cost reduction is possible due to the development of manufacturing techniques.

Tandem-type solar cells having different optical band gaps have been developed to increase the efficiency of the solar cell. The tandem-type solar cell has a form in which a top cell is stacked on a bottom cell, wherein the top cell relatively close to an incident surface of light may have a wide band gap and the bottom cell relatively far from the incident surface of light may have a narrow band gap. When the top cell is disposed on the bottom cell, the bottom cell already formed may be damaged by performing a high-temperature process. Thus, there is a need to form a bottom cell having high heat resistance.

### SUMMARY OF THE INVENTION

The present disclosure provides a tandem-type solar cell having high heat resistance.

The object of the present invention is not limited to the aforesaid, but other objects not described herein will be clearly understood by those skilled in the art from descriptions below.

An embodiment of the inventive concept provides a solar cell including a back electrode on a substrate; a first light absorbing layer including gallium (Ga) and indium (In) on the back electrode; a first buffer layer on the first light absorbing layer; a first window layer on the first buffer layer; a second light absorbing layer including Ga on the first window layer; a second buffer layer on the second light absorbing layer; and a second window layer on the second buffer layer, wherein a composition ratio of (Ga)/(Ga+In) of the first light absorbing layer is lower than that of the second light absorbing layer.

In an embodiment, the composition ratio of (Ga)/(Ga+In) of the first light absorbing layer may be in a range of about 0.23 or more to about 0.25 or less.

In an embodiment, the first buffer layer may include zinc.

In an embodiment, the first light absorbing layer may include a copper indium gallium selenide (CIGS) absorbing layer, and the second light absorbing layer may include a copper gallium selenide (CGS) absorbing layer.

In an embodiment, the second window layer may include a first sub-window layer configured to have high resistance and a second sub-window layer configured to have high transparency.

In an embodiment of the inventive concept, a solar cell includes a bottom cell having a first light absorbing layer; and a top cell which is stacked on the bottom cell and has a second light absorbing layer, wherein the first light absorbing layer includes gallium (Ga) and indium (In), and a composition ratio of (Ga)/(Ga+In) of the first light absorbing layer is in a range of about 0.23 or more to about 0.25 or less.

In an embodiment, the first light absorbing layer may include a copper indium gallium selenide (CIGS) absorbing layer, and the second light absorbing layer may include a copper gallium selenide (CGS) absorbing layer.

Particularities of other embodiments are included in the detailed description and drawings.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 illustrates a solar cell according to an embodiment of the inventive concept;

FIG. 2 is a flowchart illustrating a process of fabricating the tandem-type solar cell of FIG. 1;

FIG. 3A illustrates an open-circuit voltage according to a composition ratio of (Ga)/(Ga+In) of a first light absorbing layer, FIG. 3B illustrates an short-circuit current according to the composition ratio of (Ga)/(Ga+In) of the first light absorbing layer, FIG. 3C illustrates a fill factor (FF) according to the composition ratio of (Ga)/(Ga+In) of the first light absorbing layer, and FIG. 3D illustrates efficiency according to the composition ratio of (Ga)/(Ga+In) of the first light absorbing layer; and

FIG. 4A illustrates changes in external quantum efficiency according to a wavelength when the composition ratio of (Ga)/(Ga+In) is r4 (=0.23), FIG. 4B illustrates changes in external quantum efficiency according to the wavelength when the composition ratio of (Ga)/(Ga+In) is r5 (=0.25), FIG. 4C illustrates changes in external quantum efficiency according to the wavelength when the composition ratio of (Ga)/(Ga+In) is r6 (=0.29), FIG. 4D illustrates changes in external quantum efficiency according to the wavelength when the composition ratio of (Ga)/(Ga+In) is r7 (=0.33), and FIG. 4E illustrates changes in external quantum efficiency according to the wavelength when the composition ratio of (Ga)/(Ga+In) is r8 (=0.36).

### DETAILED DESCRIPTION OF PREFERRED EMBODIMENTS

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the inventive concept to those skilled in the art. Further, the present invention is only defined by scopes of claims. Like numbers refer to like elements throughout.

In the following description, the technical terms are used only for explaining a specific exemplary embodiment while not limiting the inventive concept. The terms of a singular form may include plural forms unless referred to the contrary. It will be understood that the terms “comprises” and/or “comprising”, when used in this specification, specify the presence of stated elements, steps, operations, and/or components, but do not preclude the presence or addition of one or more other elements, steps, operations, and/or components.

Additionally, the embodiments in the detailed description will be described with sectional and/or plan views as ideal exemplary views of the inventive concept. In the figures, the thicknesses of layers and regions are exaggerated for clarity of illustration. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate a specific shape of a device region. Thus, this should not be construed as limited to the scope of the inventive concept.

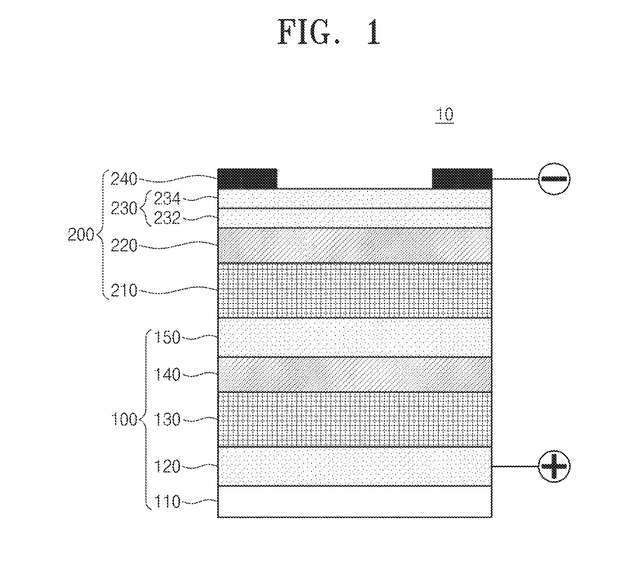

FIG. 1 illustrates a solar cell 10 according to an embodiment of the inventive concept. The solar cell 10 may be a tandem-type solar cell. In other words, the solar cell 10 may include a bottom cell 100 and a top cell 200 stacked on the bottom cell 100. For example, the bottom cell 100 may be a copper indium gallium selenide (CIGS)-based solar cell, and the top cell 200 may be a copper gallium selenide (CGS)-based solar cell.

Referring to FIG. 1, the solar cell 10 according to the embodiment of the inventive concept may include a substrate 110, a back electrode 120 on the substrate 110, a first light absorbing layer 130 on the back electrode 120, a first buffer layer 140 on the first light absorbing layer 130, a first window layer 150 on the first buffer layer 140, a second light absorbing layer 210 on the first window layer 150, a second buffer layer 220 on the second light absorbing layer 210, a second window layer 230 on the second buffer layer 220, and a grid 240 on the second window layer 230. The substrate 110, the back electrode 120, the first light absorbing layer 130, the first buffer layer 140, and the first window layer 150 may constitute the bottom cell 100, and the first window layer 150, the second light absorbing layer 210, the second buffer layer 220, the second window layer 230, and the grid 240 may constitute the top cell 200. In other words, the bottom cell 100 and the top cell 200 configured to share the first window layer 150 may constitute the tandem-type solar cell 10.

The substrate 110 may be a sodalime glass substrate, a ceramic substrate, a semiconductor substrate such as a silicon substrate, a metal substrate, a stainless steel substrate, a polyimide substrate, or a polymer substrate. For example, the substrate 110 may be a sodalime glass substrate. The back electrode 120 may be formed of a material having a small thermal expansion coefficient difference from the substrate 110 in order to prevent delamination from the substrate 110. For example, the back electrode 120 may be formed of molybdenum (Mo). Mo may have high electrical conductivity, may have ohmic contact formation characteristics with other thin films, and may have high-temperature stability in a selenium (Se) atmosphere. The first light absorbing layer 130 may be formed of a I-III-VI group compound semiconductor. The first light absorbing layer 130 may include gallium (Ga) and indium (In). For example, the first light absorbing layer 130 may be a CIGS-based absorbing layer. For example, the first light absorbing layer 130 may include a chalcopyrite-based compound semiconductor such as CuInGaSe or CuInGaSe₂. A composition ratio of (Ga)/(Ga+In) of the first light absorbing layer 130 may be in a range of about 0.23 or more to about 0.25 or less. The first buffer layer 140 may alleviate a difference in energy band gaps between the first light absorbing layer 130 and the first window layer 150. The first buffer layer 140 may have a larger energy band gap than the first light absorbing layer 130 and may have a smaller energy band gap than the first window layer 150. The first buffer layer 140, for example, may include zinc (Zn). The first window layer 150 may have excellent electro-optical characteristics. For example, the first window layer 150 may include one of indium tin oxide (ITO), transparent conductive oxide (TCO), or aluminum-doped zinc oxide (AZO) (i-ZnO).

The first window layer 150 may function as a back electrode of the top cell 200. The second light absorbing layer 210 may be formed of a I-III-IV group compound semiconductor. The second light absorbing layer 210 may include gallium (Ga). For example, the second light absorbing layer 210 may be a CGS-based absorbing layer. The composition ratio of (Ga)/(Ga+In) of the first light absorbing layer 130 may be lower than that of the second light absorbing layer 210. For example, in a case in which the second light absorbing layer 210 is a CGS-based absorbing layer, the (Ga)/(Ga+In) of the second light absorbing layer 210 may be about 1. The second buffer layer 220 may alleviate a difference in energy band gaps between the second light absorbing layer 210 and the second window layer 230. The second buffer layer 220 may have a larger energy band gap than the second light absorbing layer 210 and may have a smaller energy band gap than the second window layer 230. The second window layer 230 may have a multilayer structure. For example, the second window layer 230 may include a first sub-window layer 232 and a second sub-window layer 234 which are sequentially stacked. For example, the first sub-window layer 232 may have high resistance and the second sub-window layer 234 may have high transparency. For example, the first sub-window layer 232 may include TCO and the second sub-window layer 234 may include ITO or AZO (i-ZnO). The grid 240 may be electrically connected to the second window layer 230. The grid 240, for example, may include at least one metal layer, such as gold, silver, aluminum, and indium. Each of the first and second window layers 150 and 230, as a n-type semiconductor, may form a p-n junction with each of the first and second light absorbing layers 130 and 210, as a p-type semiconductor.

Although not shown in FIG. 1, a light scattering sheet (not shown) may be disposed on the second window layer 230. The light scattering sheet (not shown) may include an adhesive material, and, for example, may include at least one of ethylene vinyl acetate (EVA) and poly vinyl butyral (PVB).

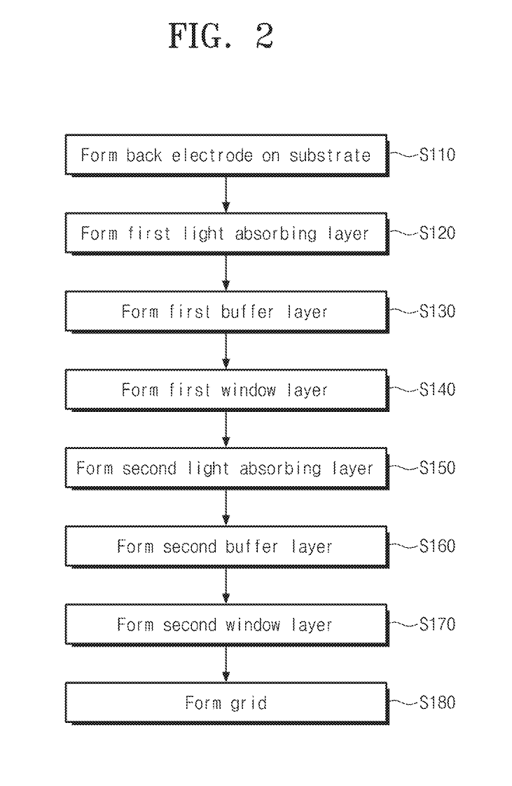

FIG. 2 is a flowchart illustrating a process of fabricating the tandem-type solar cell 10 of FIG. 1. Referring to FIGS. 1 and 2, the back electrode 120 is disposed on the substrate 110 (S110). For example, the substrate 110 may be formed of sodalime glass. The back electrode 100 may be formed of molybdenum (Mo). Mo may have high electrical conductivity, may have good ohmic contact formation characteristics with other thin films, and may have high-temperature stability in a selenium (Se) atmosphere. The back electrode 120 may be formed by using a sputtering method, for example, a direct current (DC) sputtering method.

The first light absorbing layer 130 is disposed on the back electrode 120 (S120). The first light absorbing layer 130 may include gallium (Ga) and indium (In). The first light absorbing layer 130 may be formed of a group compound semiconductor. For example, the group compound semiconductor may be a chalcopyrite-based compound semiconductor such as Cu(In,Ga)Se₂, Cu(In,Ga)(S,Se)₂, and (Au,Ag,Cu)(In,Ga,Al)(S,Se)₂. The first light absorbing layer 130 may be formed by using a co-evaporation method in which metal elements of copper (Cu), In, Ga, and Se are used as precursors.

Specifically, the first light absorbing layer 130 may be formed by a deposition process including a first step of evaporating In, Ga, and Se at the same time, a second step of evaporating Cu and Se at the same time, and a third step of evaporating In, Ga, and Se at the same time. For example, the first step may be performed in a temperature range of about 350° C. to about 450° C., the second step may be performed in a temperature range of about 480° C. to about 550° C., and the third step may be performed in a temperature range of about 480° C. to about 550° C. In this case, the composition ratio of (Ga)/(Ga+In) of the first light absorbing layer 130 may be controlled by adjusting an amount of Ga evaporated in the third step to be smaller than an amount of Ga evaporated in the first step. For example, the amount of Ga evaporated in the first step may be about 0.20 angstrom/sec, and the amount of Ga evaporated in the third step may be about 0.07 angstrom/sec. The composition ratio of (Ga)/(Ga+In) of the formed first light absorbing layer 130 may be in a range of about 0.23 or more to about 0.25 or less.

The first buffer layer 140 is further disposed on the first light absorbing layer 130 (S130). The first buffer layer 140 may alleviate a difference in energy band gaps between the first light absorbing layer 130 and the first window layer 150. The first buffer layer 140 may be formed by a sputtering method. In a case in which the first buffer layer 140 is formed by a dry process, the process may be performed in-line. Thus, the entire process may be simpler than a process in which the first buffer layer 140 is formed by a chemical bath deposition (CBD) method that requires vacuum.

The first window layer 150 is disposed on the first buffer layer 140 (S140). The first window layer 150 may be formed of a material having high light transmittance and excellent electrical conductivity. The bottom cell 100 may be completed by forming the first window layer 150.

Subsequently, the second light absorbing layer 210 is disposed on the first window layer 150 (S150). The second light absorbing layer 210 may include Ga. For example, the second light absorbing layer 210 may be a CGS-based absorbing layer. The composition ratio of (Ga)/(Ga+In) of the first light absorbing layer 130 may be lower than that of the second light absorbing layer 210. The second light absorbing layer 210 may be formed by using a co-evaporation method in which metal elements of Cu, Ga, and Se are used as precursors.

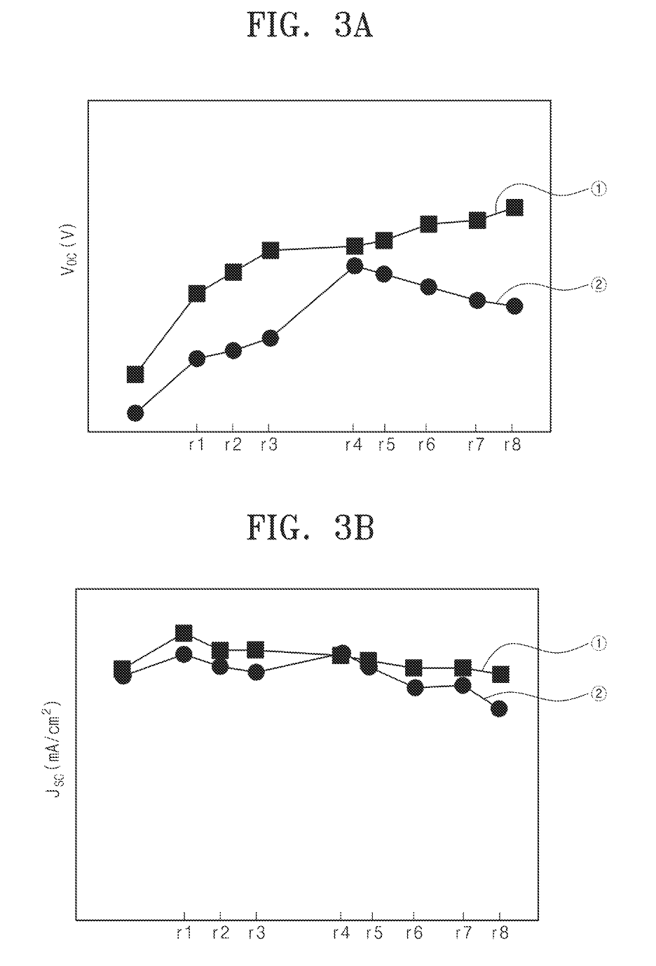

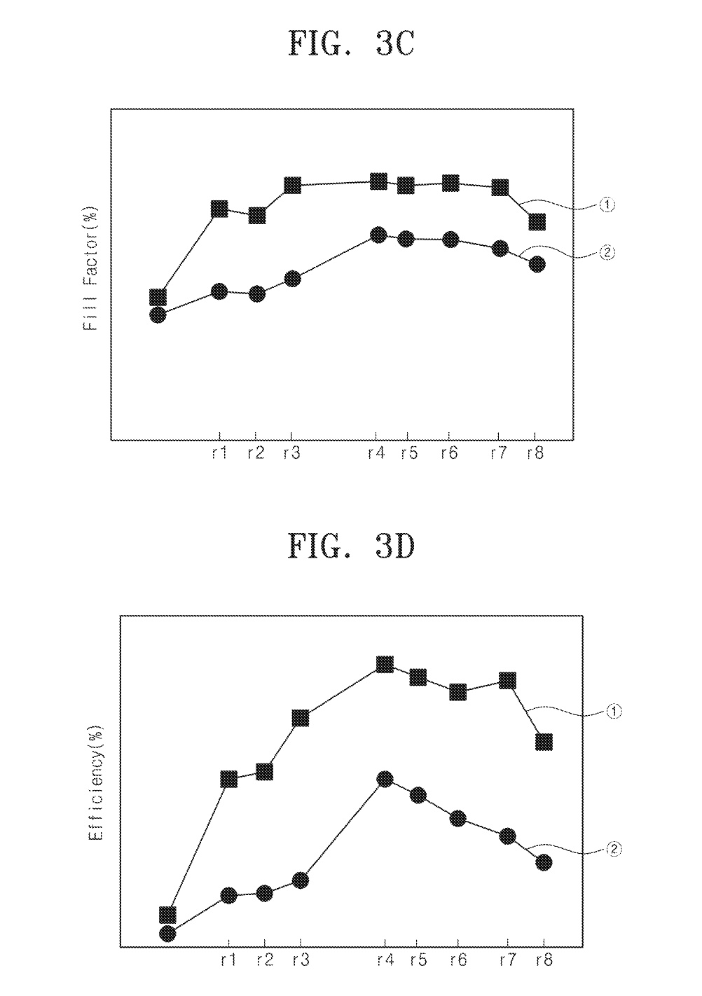

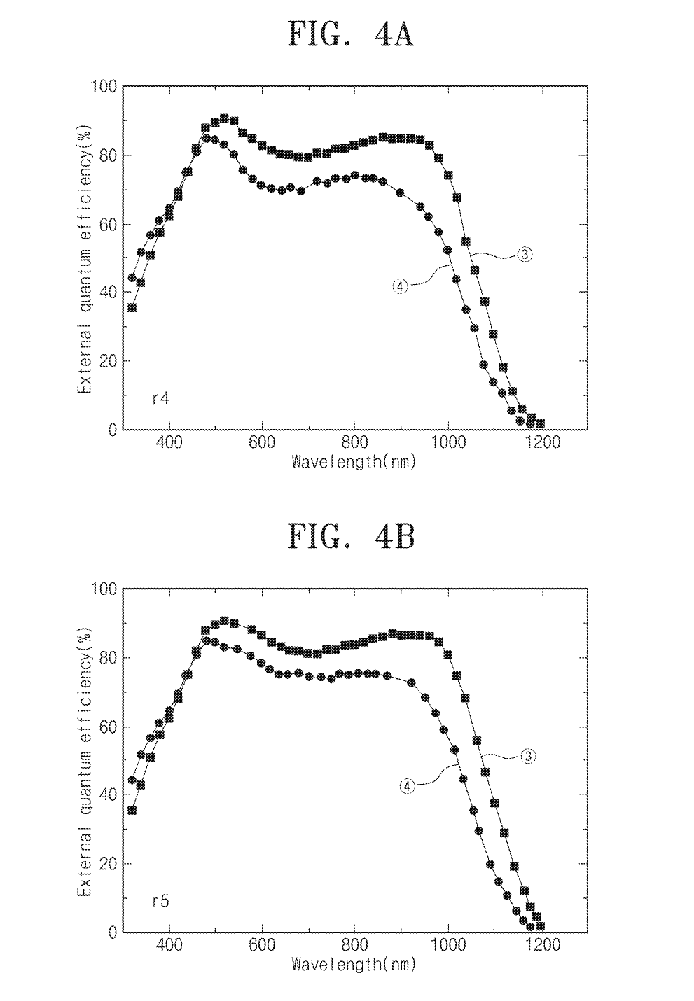

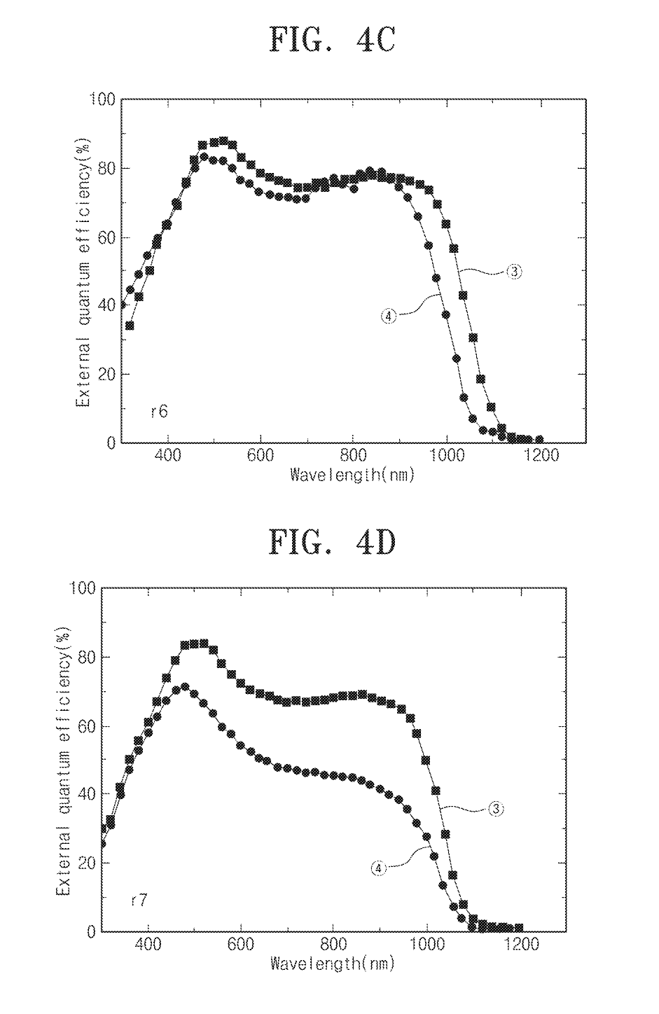

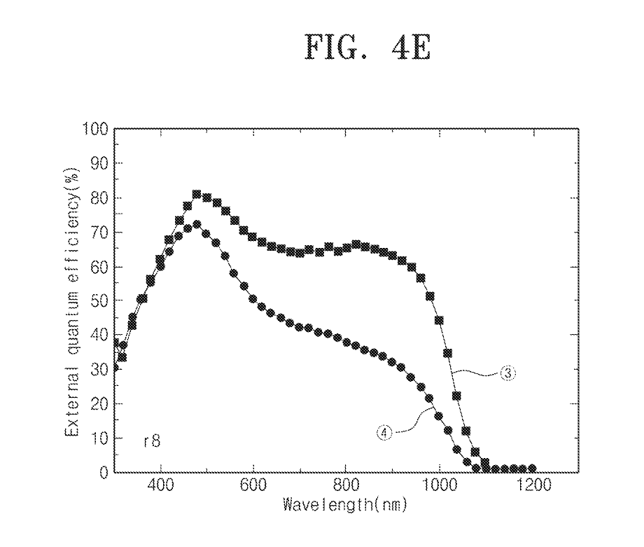

Specifically, the second light absorbing layer 210 may be formed by a deposition process including a first step of evaporating In, Ga, and Se at the same time, a second step of evaporating Cu and Se at the same time, and a third step of evaporating In, Ga, and Se at the same time. For example, the first step may be performed in a temperature range of about 350° C. to about 450° C., the second step may be performed in a temperature range of about 480° C. to about 550° C., and the third step may be performed in a temperature range of about 480° C. to about 550° C. In this case, the bottom cell 100 already formed may be damaged by the high-temperature process. For example, an element of the first buffer layer 140 may be diffused into the first light absorbing layer 130 to reduce efficiency of the bottom cell 100. Since the first buffer layer 140 includes zinc (Zn), a diffusion distance may be reduced in comparison to a case in which the first buffer layer 140 includes cadmium (Cd). Changes in the characteristics of the bottom cell 100 due to the high-temperature process will be described later with reference to FIGS. 3A to 4E.

The second buffer layer 220 is disposed on the second light absorbing layer 210 (S160). The second buffer layer 220 may alleviate a difference in energy band gaps between the second light absorbing layer 210 and the second window layer 230. The second buffer layer 220 may be formed by a sputtering method. When the second buffer layer 220 is formed by a dry process, the process may be performed in-line.

The second window layer 230 is disposed on the second buffer layer 220 (S170). The second window layer 230 may be formed of a material having high light transmittance and excellent electrical conductivity. For example, the first sub-window layer 232 and the second sub-window layer 234 may be sequentially provided. The first sub-window layer 232 may have high resistance and the second sub-window layer 234 may have high transparency. For example, the first sub-window layer 232 may include TCO and the second sub-window layer 234 may include ITO or AZO (i-ZnO). Thereafter, the grid 240 may be disposed on the second window layer 230 (S180). The grid 240 may collect current on the surface of the solar cell 10. The grid 240 may be formed of a metal such as aluminum (Al) or Nickel (Ni)/Al. The grid 240 may be formed by using a sputtering method. The top cell 200 and the tandem-type solar cell 10 may be completed by forming the grid 240.

FIGS. 3A to 3D are graphs comparing characteristics of the first light absorbing layer 130 according to before and after stacking the top cell 200 on the bottom cell 100. In other words, FIGS. 3A to 3D are graphs comparing the characteristics of the first light absorbing layer 130 of the bottom cell 100 according to the presence of the high-temperature process. FIG. 3A illustrates an open-circuit voltage (Voc) according to the composition ratio of (Ga)/(Ga+In) of the first light absorbing layer 130, FIG. 3B illustrates an short-circuit current (Jsc) according to the composition ratio of (Ga)/(Ga+In) of the first light absorbing layer 130, FIG. 3C illustrates a fill factor (FF) according to the composition ratio of (Ga)/(Ga+In) of the first light absorbing layer 130, and FIG. 3D illustrates efficiency according to the composition ratio of (Ga)/(Ga+In) of the first light absorbing layer 130. The open-circuit voltage denotes a potential difference formed at both ends of the solar cell in a state in which the circuit is open, the short-circuit current denotes a reverse current density that flows when subjected to light in a state in which external resistance is absent, and FF denotes a value obtained by dividing a product of current density and voltage at a maximum power point by a product of the open-circuit voltage and the short-circuit current. The efficiency of the solar cell is derived by reflecting the open-circuit voltage, the short-circuit current, and the FF. \textcircled{1} of FIGS. 3A to 3D represents the characteristics of the first light absorbing layer before stacking the top cell 200, and \textcircled{2} of FIGS. 3A to 3D represents the characteristics of the first light absorbing layer after stacking the top cell 200. r1, r2, r3, r4, r5, r6, r7, and r8 of FIGS. 3A to 3D are the composition ratios of (Ga)/(Ga+In), wherein r1, r2, r3, r4, r5, r6, r7, and r8 are 0.05, 0.13, 0.16, 0.23, 0.25, 0.29, 0.33, and 0.36, respectively.

Referring to \textcircled{1} of FIGS. 3A to 3D, as the composition ratio of (Ga)/(Ga+In) is increased, the open-circuit voltage is generally increased, the short-circuit current is relatively decreased, and the FF generally shows a constant value except when the composition ratio is r1 (=0.05) and r8 (=0.36). Also, in a case in which the composition ratio of (Ga)/(Ga+In) is equal to or greater than r4 (=0.23), it may be understood that the efficiency is generally high. In particular, when the composition ratio of (Ga)/(Ga+In) is r4 (=0.23), the solar cell has the highest efficiency. Referring to \textcircled{2} of FIGS. 3A to 3D, it may be confirmed that the short-circuit current is relatively less affected by the heat treatment, but the open-circuit voltage and the FF are relatively greatly affected by the heat treatment. Accordingly, it may be understood that p-n junction characteristics of the bottom cell 100 are degraded by the high-temperature process.

Subsequently, changes in external quantum efficiency according to a wavelength was measured for the case in which the efficiency is relatively high, that is, the case in which the composition ratio of (Ga)/(Ga+In) is equal to or greater than r4 (=0.23).

FIG. 4A illustrates changes in external quantum efficiency according to the wavelength when the composition ratio of (Ga)/(Ga+In) is r4 (=0.23), FIG. 4B illustrates changes in external quantum efficiency according to the wavelength when the composition ratio of (Ga)/(Ga+In) is r5 (=0.25), FIG. 4C illustrates changes in external quantum efficiency according to the wavelength when the composition ratio of (Ga)/(Ga+In) is r6 (=0.29), FIG. 4D illustrates changes in external quantum efficiency according to the wavelength when the composition ratio of (Ga)/(Ga+In) is r7 (=0.33), and FIG. 4E illustrates changes in external quantum efficiency according to the wavelength when the composition ratio of (Ga)/(Ga+In) is r8 (=0.36). \textcircled{3} of FIGS. 4A to 4E represents the characteristics of the first light absorbing layer before stacking the top cell 200, and \textcircled{4} of FIGS. 4A to 4E represents the characteristics of the first light absorbing layer after stacking the top cell 200. The expression “external quantum efficiency” may denote a ratio of electrons generated by photons.

Referring to FIGS. 4A to 4E, when the composition ratio of (Ga)/(Ga+In) is r4(=0.23), r5(=0.25), r6(=0.29), r7(=0.33), and r8(=0.36), it may be understood that the external quantum efficiencies are all reduced due to the high-temperature process. Particularly, when the composition ratio of (Ga)/(Ga+In) is r6(=0.29), r7(=0.33), and r8(=0.36), a decrease amount of the efficiency is large and/or a loss in a long wavelength region is large. For example, the long wavelength may be a wavelength of about 700 nm or more. Since the bottom cell 100 of the tandem-type solar cell 10 absorbs more of the long wavelength radiation in comparison to the top cell 200, the presence of the loss in the long wavelength region may denote the efficiency of the bottom cell of the tandem-type solar cell 10.

Thus, referring to FIGS. 3A to 4E, in a case in which the composition ratio of (Ga)/(Ga+In) of the first light absorbing layer 130 is in a range of about 0.23 to about 0.25, the efficiency and the absorption in the long wavelength region of the tandem-type solar cell 10 are better than a case in which the composition ratio is different from the above values.

According to the inventive concept, the tandem-type solar cell 10 having high heat resistance may be provided. In particular, the tandem-type solar cell 10 having high heat resistance may be provided by controlling the composition ratio of (Ga)/(Ga+In) of the first light absorbing layer 130 of the bottom cell 100 to be in a range of about 0.23 or more to about 0.25 or less. For example, the first light absorbing layer 130 having a composition ratio of (Ga)/(Ga+In) of about 0.23 or more to about 0.25 or less may function as a diffusion barrier layer to prevent diffusion of a predetermined concentration of Ga at an interface between the first light absorbing layer 130 and the first buffer layer 140.

According to embodiments of the inventive concept, a tandem-type solar cell having high heat resistance may be provided.

Although preferred embodiments of the inventive concept have been shown and described with reference to the accompanying drawings, it will be understood by those of ordinary skill in the art that various changes in form and details may be made therein without departing from the spirit and scope of the invention as defined by the following claims. Accordingly, it is to be understood that the inventive concept has been described by way of illustration and not limitation.

What is claimed is:

1. A solar cell comprising:
a back electrode on a substrate;
a first light absorbing layer including gallium (Ga) and indium (In) on the back electrode;
a first buffer layer on the first light absorbing layer;
a first window layer on the first buffer layer;
a second light absorbing layer including Ga on the first window layer;
a second buffer layer on the second light absorbing layer; and
a second window layer on the second buffer layer,
wherein a composition ratio of (Ga)/(Ga+In) of the first light absorbing layer is lower than that of the second light absorbing layer.

2. The solar cell of claim 1, wherein the composition ratio of (Ga)/(Ga+In) of the first light absorbing layer is in a range of about 0.23 or more to about 0.25 or less.

3. The solar cell of claim 1, wherein the first buffer layer comprises zinc.

4. The solar cell of claim 1, wherein the first light absorbing layer comprises a copper indium gallium selenide (CIGS) absorbing layer, and the second light absorbing layer comprises a copper gallium selenide (CGS) absorbing layer.

5. The solar cell of claim 1, wherein the second window layer comprises:
a first sub-window layer configured to have high resistance; and
a second sub-window layer configured to have high transparency.

6. A solar cell comprising:
a bottom cell having a first light absorbing layer; and
a top cell which is stacked on the bottom cell and has a second light absorbing layer,
wherein the first light absorbing layer comprises gallium (Ga) and indium (In), and a composition ratio of (Ga)/(Ga+In) of the first light absorbing layer is in a range of about 0.23 or more to about 0.25 or less.

7. The solar cell of claim 6, wherein the first light absorbing layer comprises a copper indium gallium selenide (CIGS) absorbing layer, and the second light absorbing layer comprises a copper gallium selenide (CGS) absorbing layer.
